(19) United States
(12) Patent Application Publication
(10) Pub. No.: US 2026/0239729 A1
(43) Pub. Date: Aug. 13, 2026

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Meng-Han Lin, Hsinchu City (TW); Yu-Chang Lin, Hsinchu (TW)

(73) Assignee: Powerchip Semiconductor Manufacturing Corporation, Hsinchu (TW)

(21) Appl. No.: 19/207,310

(22) Filed: May 13, 2025

(30) Foreign Application Priority Data
Feb. 12, 2025 (TW) 114105124

(51) Int. Cl. H10D 84/83; H10D 84/01

(52) U.S. Cl. CPC H10D 84/835; H10D 84/0142; H10D 84/0149; H10D 84/83138

(57) ABSTRACT

A semiconductor structure includes a substrate, a transistor device, a first back gate, a second back gate, and a dielectric layer. The substrate has a front side and a back side opposite to each other. The transistor device is located on the front side. The transistor device includes a first drift region and a second drift region. The first drift region and the second drift region are located in the substrate. The first back gate is located on the back side. The first back gate extends into the first drift region. The second back gate is located on the back side. The second back gate extends into the second drift region. The dielectric layer is located between the first back gate and the substrate, and between the second back gate and the substrate.

### CROSS-REFERENCE TO RELATED APPLICATION

This application claims the priority benefit of Taiwan application serial no. 114105124, filed on February 12, 2025. The entirety of the above-mentioned patent application is hereby incorporated by reference herein and made a part of this specification.

### BACKGROUND

### Technical Field

The disclosure relates to a semiconductor structure and a manufacturing method thereof, and particularly relates to a semiconductor structure with a back electrode and a manufacturing method thereof.

### Related Art

Transistor devices are widely used in various electronic products. As technology advances, the size of electronic components continues to shrink, making it more challenging to increase the breakdown voltage of transistor devices and reduce the on-resistance thereof. Therefore, how to increase the breakdown voltage of transistor devices and reduce the on-resistance thereof has become a constant goal of effort.

### SUMMARY

The disclosure provides a semiconductor structure and a manufacturing method thereof, which can increase the breakdown voltage of transistor devices and reduce the on-resistance thereof.

The disclosure proposes a semiconductor structure, which includes a substrate, a transistor device, a first back gate, a second back gate, and a dielectric layer. The substrate has a front side and a back side opposite to each other. The transistor device is located on the front side. The transistor device includes a first drift region and a second drift region. The first drift region and the second drift region are located in the substrate. The first back gate is located on the back side. The first back gate extends into the first drift region. The second back gate is located on the back side. The second back gate extends into the second drift region. The dielectric layer is located between the first back gate and the substrate, and between the second back gate and the substrate.

According to an embodiment of the disclosure, the semiconductor structure may further include a conductive layer. The conductive layer is located on the first back gate and the second back gate. The conductive layer may be electrically connected to the first back gate and the second back gate.

According to an embodiment of the disclosure, in the semiconductor structure, the transistor device may further include a gate and a gate dielectric layer. The gate is located on the front side. The gate is located above a portion of the first drift region and a portion of the second drift region. The gate dielectric layer is located between the gate and the substrate.

According to an embodiment of the disclosure, in the semiconductor structure, the first back gate may have a first protrusion extending into the first drift region. The second back gate may have a second protrusion extending into the second drift region.

According to an embodiment of the disclosure, in the semiconductor structure, the gate may have a first sidewall and a second sidewall opposite to each other. The first sidewall may be located directly above the first drift region. The second sidewall may be located directly above the second drift region. The first protrusion may have a third sidewall away from the second protrusion. The second protrusion may have a fourth sidewall away from the first protrusion.

According to an embodiment of the disclosure, in the semiconductor structure, the third sidewall does not extend beyond the first sidewall, and the fourth sidewall does not extend beyond the second sidewall.

According to an embodiment of the disclosure, in the semiconductor structure, the third sidewall may be aligned with the first sidewall, and the fourth sidewall may be aligned with the second sidewall.

According to an embodiment of the disclosure, in the semiconductor structure, the third sidewall may extend beyond the first sidewall, and the fourth sidewall may extend beyond the second sidewall.

According to an embodiment of the disclosure, in the semiconductor structure, the transistor device may further include a first isolation structure and a second isolation structure. The first isolation structure is located in the first drift region. The second isolation structure is located in the second drift region. The gate is located above a portion of the first isolation structure and a portion of the second isolation structure.

According to an embodiment of the disclosure, in the semiconductor structure, the transistor device may further include a first doped region and a second doped region. The first doped region is located in the first drift region. The second doped region is located in the second drift region. The first isolation structure and the second isolation structure may be located between the first doped region and the second doped region.

According to an embodiment of the disclosure, in the semiconductor structure, the transistor device may further include a first well region and a second well region. The first well region and the second well region are located in the substrate on both sides of the gate. The first drift region and the second drift region may be located between the first well region and the second well region.

According to an embodiment of the disclosure, in the semiconductor structure, the transistor device may further include a first doped region and a second doped region. The first doped region is located in the first well region. The second doped region is located in the second well region.

According to an embodiment of the disclosure, in the semiconductor structure, the transistor device may further include a third well region. The first drift region, the second drift region, the first well region, and the second well region may be located in the third well region.

According to an embodiment of the disclosure, in the semiconductor structure, the transistor device may be mirror-symmetrical.

The disclosure proposes a manufacturing method of a semiconductor structure, which includes steps as follows. A substrate is provided. The substrate has a front side and a back side opposite to each other. A transistor device is formed on the front side. The transistor device includes a first drift region and a second drift region. The first drift region and the second drift region are located in the substrate. A first back gate and a second back gate are formed on the back side. The first back gate extends into the first drift region. The second back gate extends into the second drift region. A first dielectric layer is formed between the first back gate and the substrate, and between the second back gate and the substrate.

According to an embodiment of the disclosure, in the manufacturing method of the semiconductor structure, a method of forming the first dielectric layer may include steps as follows. Patterning is performed on the back side to form a first recess and a second recess. The first recess may expose the first drift region. The second recess may expose the second drift region. The first dielectric layer is conformally formed on the back side and in the first recess and the second recess.

According to an embodiment of the disclosure, in the manufacturing method of the semiconductor structure, the first recess may extend into the first drift region. The second recess may extend into the second drift region.

According to an embodiment of the disclosure, in the manufacturing method of the semiconductor structure, a method of forming the first back gate and the second back gate may include steps as follows. A second dielectric layer is formed on the first dielectric layer. The second dielectric layer may fill the first recess and the second recess. The first back gate and the second back gate are formed in the second dielectric layer. A portion of the first back gate may be located in the first recess. A portion of the second back gate may be located in the second recess.

According to an embodiment of the disclosure, the manufacturing method of the semiconductor structure may further include steps as follows. A conductive layer is formed on the first back gate and the second back gate. The conductive layer may be electrically connected to the first back gate and the second back gate.

According to an embodiment of the disclosure, in the manufacturing method of the semiconductor structure, a method of forming the conductive layer may include steps as follows. A third dielectric layer is formed on the second dielectric layer, the first back gate, and the second back gate. The conductive layer is formed in the third dielectric layer.

Based on the above, in the semiconductor structure and the manufacturing method thereof proposed by the disclosure, the first back gate extends into the first drift region, and the second back gate extends into the second drift region. Therefore, the breakdown voltage of the transistor device can be increased and the on-resistance of the transistor device can be reduced through the first back gate and the second back gate.

To make the foregoing features and advantages of the disclosure more comprehensible, exemplary embodiments are described below in detail with reference to the accompanying drawings.

### BRIEF DESCRIPTION OF THE DRAWINGS

FIGS. 1A to FIG. 1H are cross-sectional views illustrating a manufacturing process of a semiconductor structure according to some embodiments of the disclosure.

FIG. 2 is a cross-sectional view of the semiconductor structure according to some other embodiments of the disclosure.

FIG. 3 is a cross-sectional view of the semiconductor structure according to still some other embodiments of the disclosure.

### DESCRIPTION OF THE EMBODIMENTS

The following embodiments are described in detail with reference to the accompanying drawings, but the provided embodiments are not intended to limit the scope covered by the disclosure. For ease of understanding, the same components in the following description will be denoted by the same reference numerals. Furthermore, the accompanying drawings are merely for illustrative purposes and are not drawn to scale. In fact, for clarity of discussion, the dimensions of various features may be arbitrarily increased or reduced.

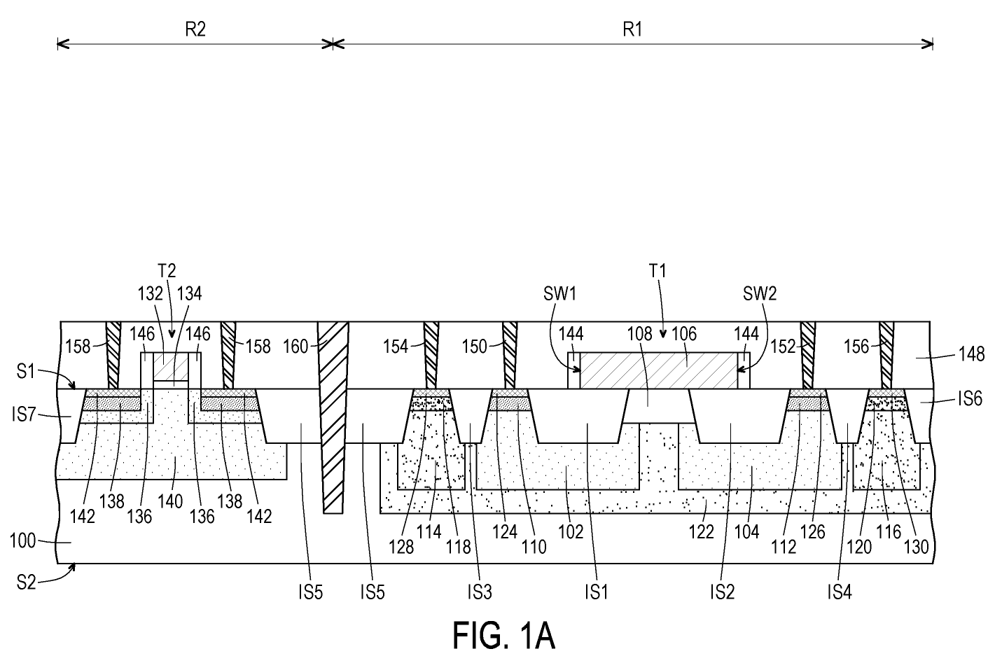

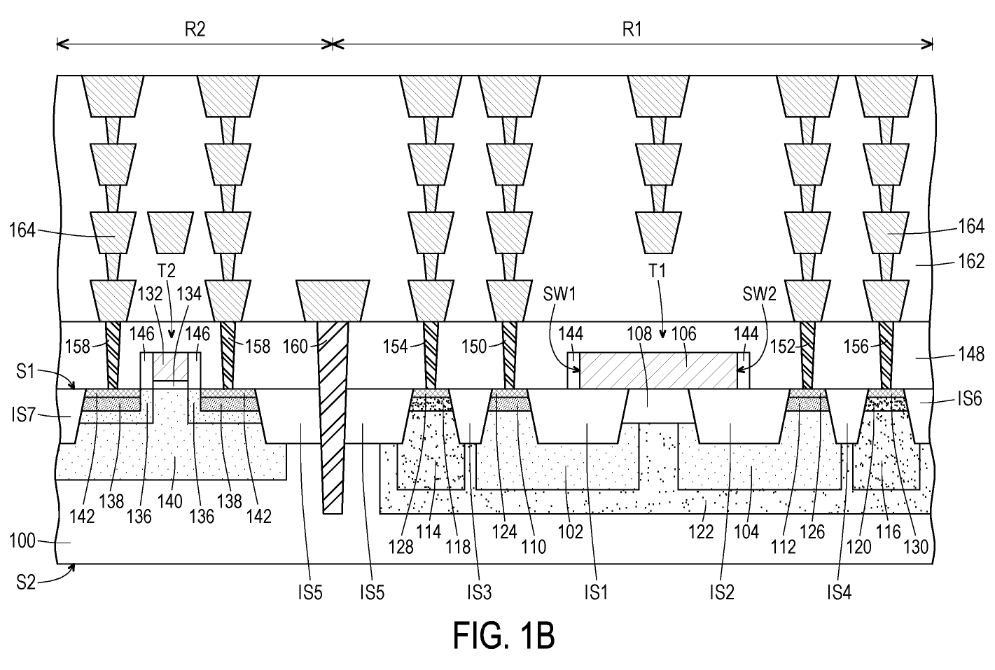

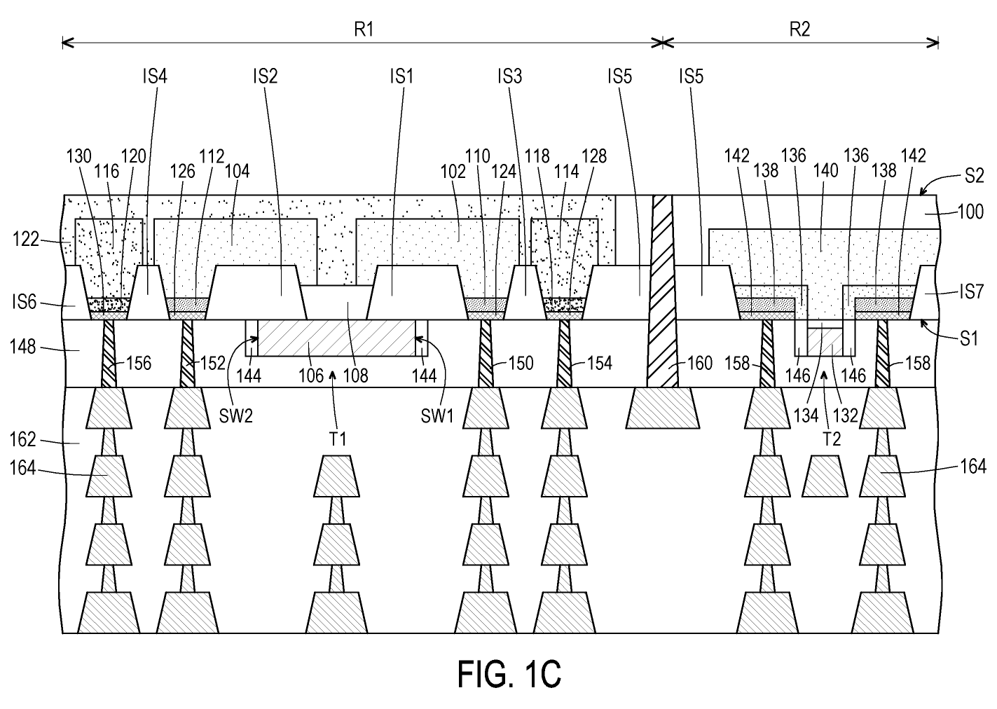

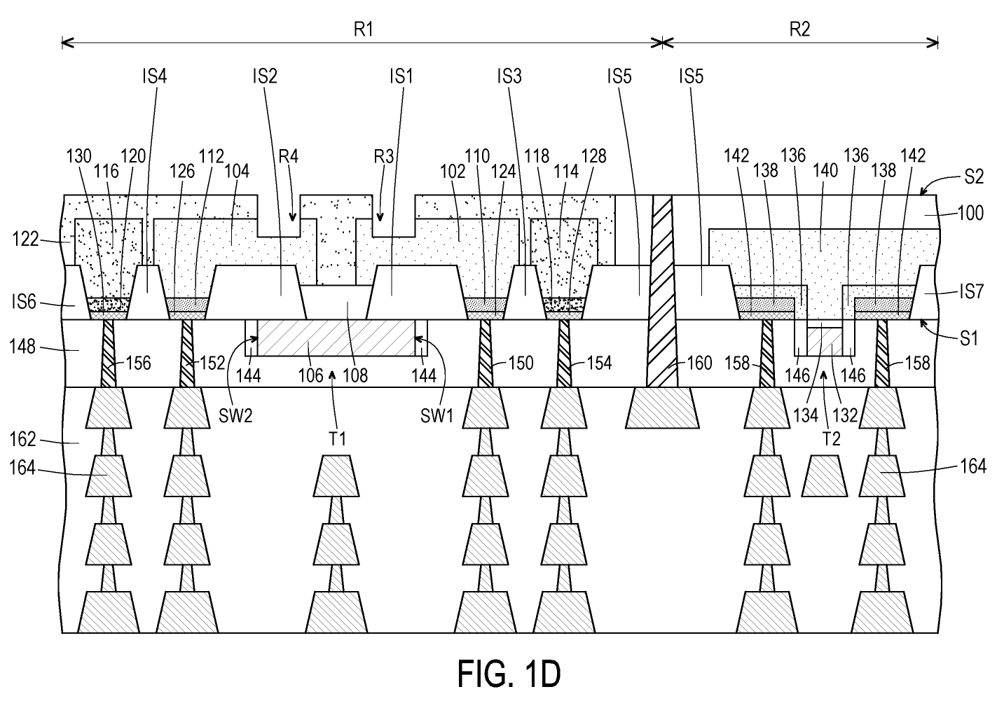

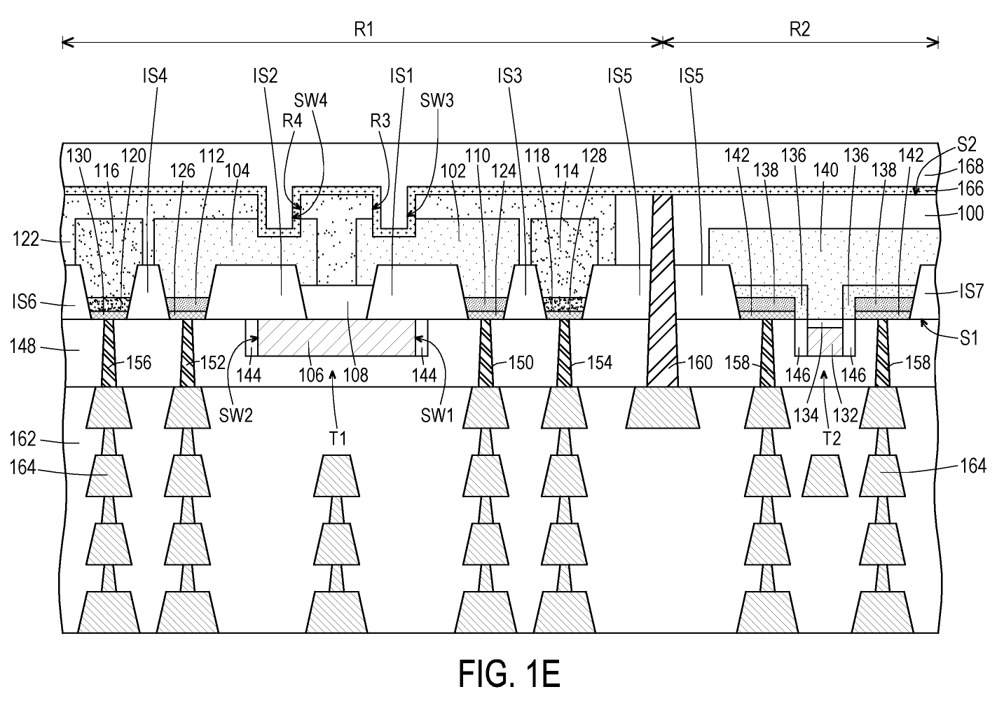

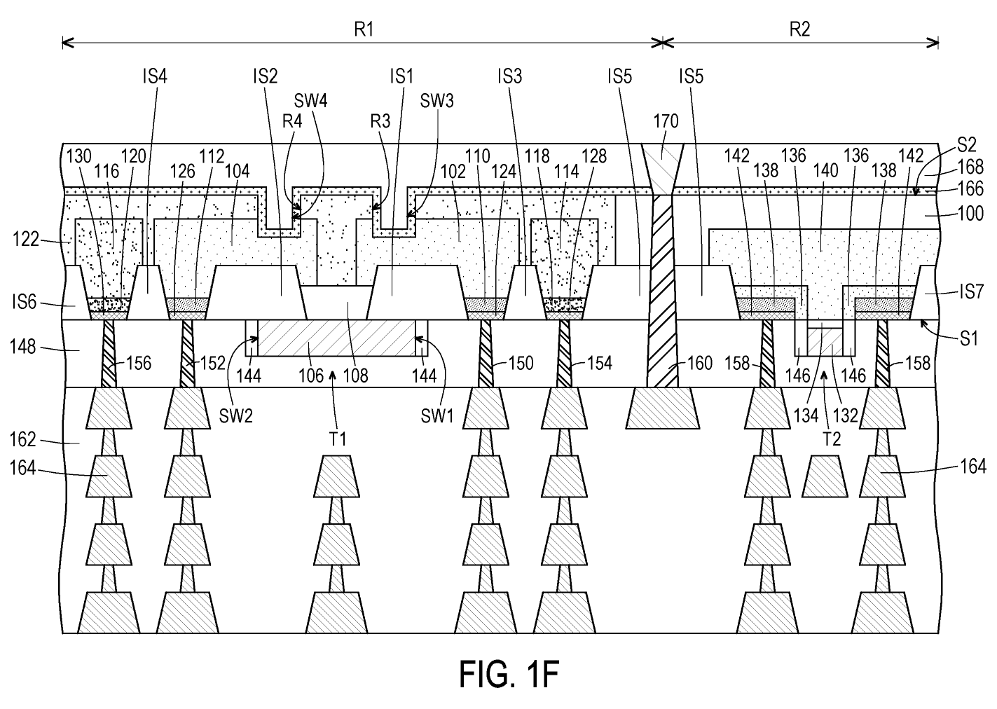

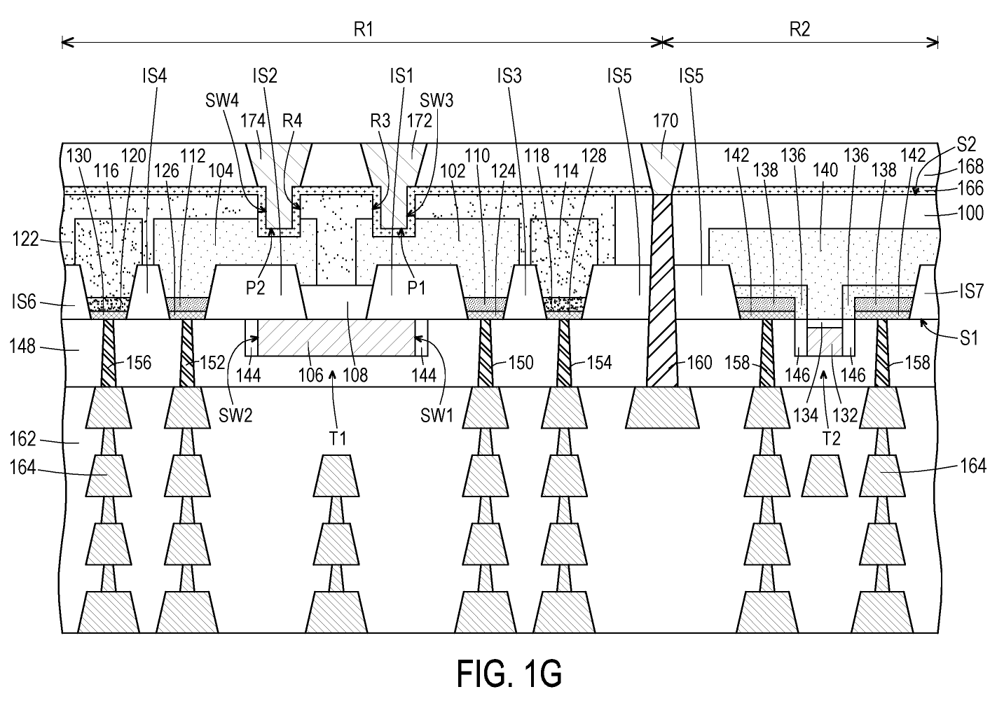

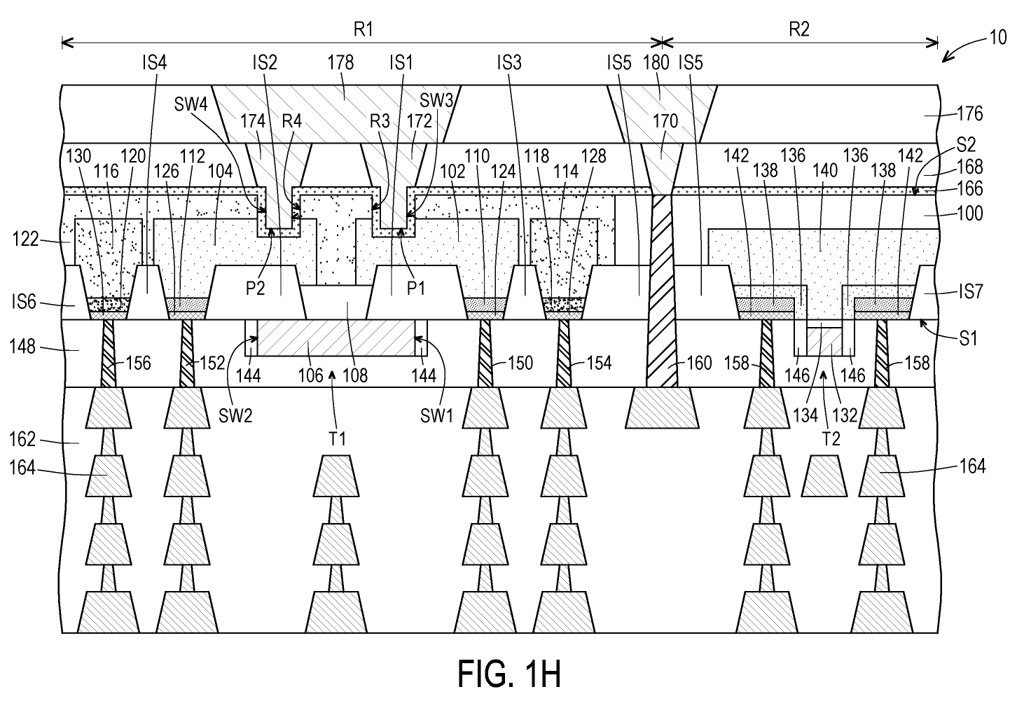

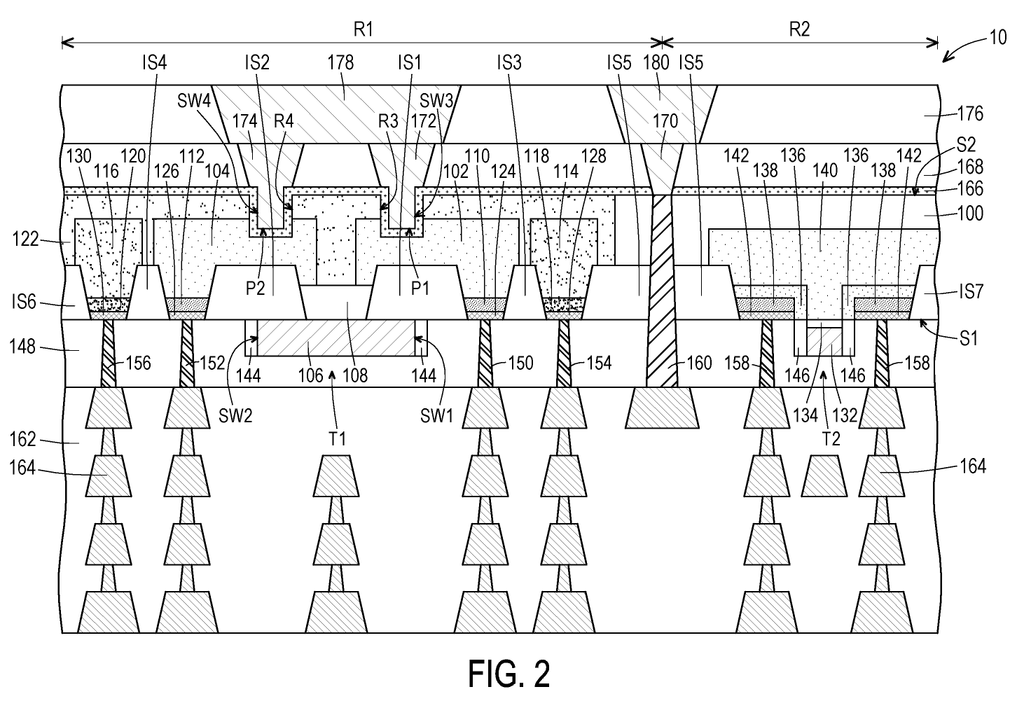

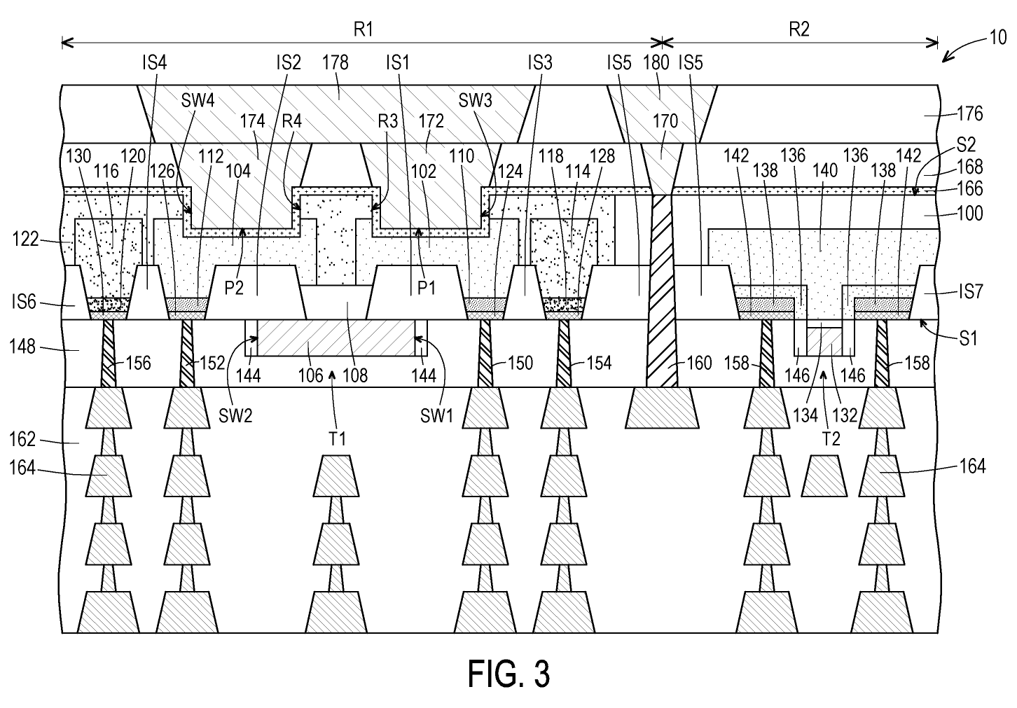

FIGS. 1A to FIG. 1H are cross-sectional views illustrating a manufacturing process of a semiconductor structure according to some embodiments of the disclosure. FIG. 2 is a cross-sectional view of the semiconductor structure according to some other embodiments of the disclosure. FIG. 3 is a cross-sectional view of the semiconductor structure according to still some other embodiments of the disclosure.

Referring to FIG. 1A, a substrate 100 is provided. The substrate 100 has a front side S1 and a back side S2 opposite to each other. In some embodiments, the substrate 100 may include a first region R1 and a second region R2. In some embodiments, the first region R1 may be a device region with a high voltage device, and the second region R2 may be a device region with a core device. In some embodiments, the threshold voltage of the high voltage device may be higher than the threshold voltage of the core device. In some embodiments, the substrate 100 may be a semiconductor substrate, such as a silicon substrate.

Next, a transistor device T1 is formed on the front side S1. The transistor device T1 may be located in the first region R1. The transistor device T1 includes a drift region 102 and a drift region 104. The drift region 102 and the drift region 104 are located in the substrate 100. In addition, the transistor device T1 may further include an isolation structure IS1 and an isolation structure IS2. The isolation structure IS1 is located in the drift region 102. The isolation structure IS2 is located in the drift region 104. In some embodiments, the isolation structure IS1 and the isolation structure IS2 may be shallow trench isolation structures.

The transistor device T1 may further include a gate 106 and a gate dielectric layer 108. The gate 106 is located on the front side S1. The gate 106 is located above a portion of the drift region 102 and a portion of the drift region 104. The gate 106 is located above a portion of the isolation structure IS1 and a portion of the isolation structure IS2. The gate 106 may have a sidewall SW1 and a sidewall SW2 opposite to each other. The sidewall SW1 may be located directly above the drift region 102. The sidewall SW2 may be located directly above the drift region 104. In some embodiments, the gate 106 may be a poly gate or a metal gate. The gate dielectric layer 108 is located between the gate 106 and the substrate 100. In some embodiments, the material of the gate 106 may be doped polysilicon, and the material of the gate dielectric layer 108 may be silicon oxide, but the disclosure is not limited thereto. In some other embodiments, the gate 106 and the gate dielectric layer 108 may be formed by high-k metal gate (HKMG) technology.

The transistor device T1 may further include a doped region 110 and a doped region 112. In some embodiments, the doped region 110 and the doped region 112 may be used as source/drain regions. The doped region 110 is located in the drift region 102. The doped region 112 is located in the drift region 104. The isolation structure IS1 and the isolation structure IS2 may be located between the doped region 110 and the doped region 112. The transistor device T1 may further include a well region 114 and a well region 116. The well region 114 and the well region 116 are located in the substrate 100 on both sides of the gate 106. The drift region 102 and the drift region 104 may be located between the well region 114 and the well region 116. The transistor device T1 may further include a doped region 118 and a doped region 120. The doped region 118 is located in the well region 114. The doped region 120 is located in the well region 116. The transistor device T1 may further include a well region 122. The drift region 102, the drift region 104, the well region 114, and the well region 116 may be located in the well region 122.

The transistor device T1 may further include a metal silicide layer 124, a metal silicide layer 126, a metal silicide layer 128, and a metal silicide layer 130. The metal silicide layer 124, the metal silicide layer 126, the metal silicide layer 128, and the metal silicide layer 130 are respectively located on the doped region 110, the doped region 112, the doped region 118, and the doped region 120,.

In some embodiments, a transistor T2 may be formed in the second region R2. The transistor T2 is located on the front side S1. The transistor T2 may be a planar transistor or a fin field-effect transistor (FinFET). In this embodiment, the transistor T2 is exemplified as a planar transistor, but the disclosure is not limited thereto. The transistor T2 may include a gate 132, a gate dielectric layer 134, multiple lightly doped drain (LDD) regions 136, multiple source/drain regions 138, a well region 140, and multiple metal silicide layers 142. The gate 132 is located on the front side S1 of the substrate 100. In some embodiments, the gate 132 may be a poly gate or a metal gate. The gate dielectric layer 134 is located between the gate 132 and the substrate 100. In some embodiments, the material of the gate 132 may be doped polysilicon, and the material of the gate dielectric layer 134 may be silicon oxide, but the disclosure is not limited thereto. In some other embodiments, the gate 132 and the gate dielectric layer 134 may be formed by high-k metal gate (HKMG) technology. The multiple lightly doped drain regions 136 are located in the substrate 100 on both sides of the gate 132. The multiple source/drain regions 138 are located in the multiple lightly doped drain regions 136. The multiple lightly doped drain regions 136 and the multiple source/drain regions 138 are located in the well region 140. The multiple metal silicide layers 142 are located on the multiple source/drain regions 138.

In some embodiments, the substrate may further include an isolation structure IS3, an isolation structure IS4, an isolation structure IS5, an isolation structure IS6, and an isolation structure IS7. The doped region 110 is located between the isolation structure IS1 and the isolation structure IS3. The doped region 112 is located between the isolation structure IS2 and the isolation structure IS4. The doped region 118 is located between the isolation structure IS3 and the isolation structure IS5. The doped region 120 is located between the isolation structure IS4 and the isolation structure IS6. The multiple doped regions 138 are located between the isolation structure IS5 and the isolation structure IS7. In some embodiments, the isolation structure IS3, the isolation structure IS4, the isolation structure IS5, the isolation structure IS6, and the isolation structure IS7 may be shallow trench isolation structures.

In some embodiments, gap walls 144 may be formed on the sidewall SW1 and the sidewall SW2 of the gate 106, and gap walls 146 may be formed on the sidewalls of the gate 132. The gap walls 144 and the gap walls 146 may be single-layer structures or multi-layer structures. In some embodiments, the material of the gap walls 144 and the material of the gap walls 146 may be, for example, silicon oxide, silicon nitride, or a combination thereof.

Subsequently, a dielectric layer 148 may be formed on the substrate 100. The dielectric layer 148 may be a single-layer structure or a multi-layer structure. In some embodiments, the material of the dielectric layer 148 may be, for example, silicon oxide, silicon nitride, or a combination thereof.

Then, a contact window 150, a contact window 152, a contact window 154, a contact window 156, and multiple contact windows 158 may be formed in the dielectric layer 148. The contact window 150, the contact window 152, the contact window 154, the contact window 156, and the multiple contact windows 158 may be electrically connected to the doped region 110, the doped region 112, the doped region 118, the doped region 120, and the multiple doped regions 138, respectively. The material of the contact window 150, the material of the contact window 152, the material of the contact window 154, the material of the contact window 156, and the material of the multiple contact windows 158 may be, for example, tungsten, titanium, titanium nitride, or a combination thereof.

Next, a via 160 may be formed in the substrate 100, the isolation structure IS5, and the dielectric layer 148. The via 160 may be used as a power via. In some embodiments, the material of the via 160 may be, for example, titanium, titanium nitride, tungsten, aluminum, tantalum nitride, copper, cobalt, or a combination thereof.

Referring to FIG. 1B, a dielectric layer 162 and multiple interconnect structures 164 of the back end of line (BEOL) may be formed on the dielectric layer 148. In some embodiments, the dielectric layer 162 may be a multi-layer structure. The material of the dielectric layer 162 may be, for example, silicon oxide, silicon nitride, or a combination thereof. The multiple interconnect structures 164 are located in the dielectric layer 162. A portion of the multiple interconnect structures 164 may be electrically connected to the contact window 150, a portion of the multiple interconnect structures 164 may be electrically connected to the contact window 152, a portion of the multiple interconnect structures 164 may be electrically connected to the contact window 154, a portion of the multiple interconnect structures 164 may be electrically connected to the contact window 156, a portion of the multiple interconnect structures 164 may be electrically connected to the multiple contact windows 158, and a portion of the multiple interconnect structures 164 may be electrically connected to the via 160. The material of the interconnect structures 164 may be, for example, copper, aluminum, tungsten, tantalum, tantalum nitride, titanium, titanium nitride, or a combination thereof.

Referring to FIG. 1C, a thinning process may be performed on the back side S2, thereby reducing the thickness of the substrate 100 and exposing the via 160. As a result, the via 160 may penetrate through the substrate 100. In some embodiments, the thinning process may be, for example, a grinding process or a chemical mechanical polishing process.

Referring to FIG. 1D, the back side S2 may be patterned to form a recess R3 and a recess R4. The recess R3 may expose the drift region 102. The recess R4 may expose the drift region 104. The recess R3 may extend into the drift region 102. The recess R4 may extend into the drift region 104. In some embodiments, the back side S2 may be patterned by a lithography process and an etching process.

Referring to FIG. 1E, a dielectric layer 166 may be conformally formed on the back side S2 and in the recess R3 and the recess R4. In some embodiments, the material of the dielectric layer 166 may be, for example, a metal oxide. In some embodiments, a method of forming the dielectric layer 166 may be, for example, chemical vapor deposition or atomic layer deposition.

Next, a dielectric layer 168 may be formed on the dielectric layer 166. The dielectric layer 168 may fill the recess R3 and the recess R4. In some embodiments, the material of the dielectric layer 168 may be, for example, silicon oxide. In some embodiments, a method of forming the dielectric layer 168 may be, for example, chemical vapor deposition.

Referring to FIG. 1F, a via 170 may be formed in the dielectric layer 168 and the dielectric layer 166. The via 170 may be electrically connected to the via 160. In some embodiments, the material of the via 170 may be, for example, copper, aluminum, tungsten, tantalum, tantalum nitride, titanium, titanium nitride, or a combination thereof.

Referring to FIG. 1G, a back gate 172 and a back gate 174 may be formed in the dielectric layer 168. A portion of the back gate 172 may be located in the recess R3, forming a protrusion P1. A portion of the back gate 174 may be located in the recess R4, forming a protrusion P2. As a result, the back gate 172 and the back gate 174 may be formed on the back side S2. The back gate 172 extends into the drift region 102. The back gate 174 extends into the drift region 104. By the aforementioned method, the dielectric layer 166 may be formed between the back gate 172 and the substrate 100, and between the back gate 174 and the substrate 100. The protrusion P1 may directly contact the dielectric layer 166. The protrusion P2 may directly contact the dielectric layer 166. In some embodiments, the material of the back gate 172 and the material of the back gate 174 may be, for example, copper, aluminum, tungsten, tantalum, tantalum nitride, titanium, titanium nitride, or a combination thereof.

Referring to FIG. 1H, a dielectric layer 176 may be formed on the dielectric layer 168, the via 170, the back gate 172, and the back gate 174. In some embodiments, the material of the dielectric layer 176 may be, for example, silicon oxide. In some embodiments, a method of forming the dielectric layer 168 may be, for example, chemical vapor deposition.

Next, a conductive layer 178 and a conductive layer 180 may be formed in the dielectric layer 176. As a result, the conductive layer 178 may be formed on the back gate 172 and the back gate 174, and the conductive layer 180 may be formed on the via 170. The conductive layer 178 may be electrically connected to the back gate 172 and the back gate 174. The conductive layer 180 may be electrically connected to the via 170. In some embodiments, the material of the conductive layer 178 and the material of the conductive layer 180 may be, for example, copper, aluminum, tungsten, tantalum, tantalum nitride, titanium, titanium nitride, or a combination thereof.

The following description explains the semiconductor structure 10 of the foregoing embodiments with reference to FIG. 1H. Moreover, although the method of forming the semiconductor structure 10 is illustrated using the foregoing method as an example, the disclosure is not limited thereto.

Referring to FIG. 1H, the semiconductor structure 10 includes a substrate 100, a transistor device T1, a back gate 172, a back gate 174, and a dielectric layer 166. In some embodiments, the semiconductor structure 10 may be applied to a packaging structure of a three-dimensional integrated circuit (3D IC). The substrate 100 has a front side S1 and a back side S2 opposite to each other. In some embodiments, the substrate 100 may include a first region R1 and a second region R2. The transistor device T1 may be located in the first region R1. The transistor device T1 is located on the front side S1. In some embodiments, the transistor device T1 may be mirror-symmetrical. For example, the transistor device T1 may be mirror-symmetrical with respect to a central axis passing through the transistor device T1. The transistor device T1 includes a drift region 102 and a drift region 104. The drift region 102 and the drift region 104 are located in the substrate 100. In some embodiments, the semiconductor structure 10 may further include a transistor device T2. The transistor device T2 may be located in the second region R2. The transistor device T2 is located on the front side S1. Furthermore, the transistor T1 and the transistor T2 have been described in detail in the foregoing embodiments, so details will not be repeated here.

The back gate 172 is located on the back side S2. The back gate 172 extends into the drift region 102. The back gate 174 is located on the back side S2. The back gate 174 extends into the drift region 104. The back gate 172 may have a protrusion P1 extending into the drift region 102. The back gate 174 may have a protrusion P2 extending into the drift region 104. The protrusion P1 may have a sidewall SW3 away from the protrusion P2. The protrusion P2 may have a sidewall SW4 away from the protrusion P1. In this embodiment, as shown in FIG. 1H, the sidewall SW3 does not extend beyond the sidewall SW1, and the sidewall SW4 does not extend beyond the sidewall SW2, but the disclosure is not limited thereto. In some other embodiments, as shown in FIG. 2, the sidewall SW3 may be aligned with the sidewall SW1, and the sidewall SW4 may be aligned with the sidewall SW2. In still some other embodiments, as shown in FIG. 3, the sidewall SW3 may extend beyond the sidewall SW1, and the sidewall SW4 may extend beyond the sidewall SW2.

The dielectric layer 166 is located between the back gate 172 and the substrate 100, and between the back gate 174 and the substrate 100. The semiconductor structure 10 may further include a conductive layer 178. The conductive layer 178 is located on the back gate 172 and the back gate 174. The conductive layer 178 may be electrically connected to the back gate 172 and the back gate 174. Furthermore, for the remaining components in the semiconductor structure 10, reference may be made to the descriptions in the foregoing embodiments. In addition, the detailed contents (such as materials and manufacturing methods) of the respective components in the semiconductor structure 10 have been described in detail in the foregoing embodiments, so details will not be repeated here.

Based on the foregoing embodiments, it may be known that in the semiconductor structure 10 and the manufacturing method thereof, the back gate 172 extends into the drift region 102, and the back gate 174 extends into the drift region 104. Therefore, the breakdown voltage of the transistor device T1 can be increased and the on-resistance of the transistor device T1 can be reduced through the back gate 172 and the back gate 174.

In summary, in the semiconductor structure and the manufacturing method thereof according to the foregoing embodiments, the semiconductor structure includes a substrate, a transistor device, a first back gate, a second back gate, and a dielectric layer. The substrate has a front side and a back side opposite to each other. The transistor device is located on the front side. The transistor device includes a first drift region and a second drift region. The first drift region and the second drift region are located in the substrate. The first back gate is located on the back side. The first back gate extends into the first drift region. The second back gate is located on the back side. The second back gate extends into the second drift region. The dielectric layer is located between the first back gate and the substrate, and between the second back gate and the substrate. Since the first back gate extends into the first drift region, and the second back gate extends into the second drift region, the breakdown voltage of the transistor device can be increased and the on-resistance of the transistor device can be reduced through the first back gate and the second back gate.

Although the disclosure has been disclosed by the foregoing embodiments, the embodiments are not intended to limit the disclosure. Persons skilled in the art may make some changes and modifications without departing from the spirit and scope of the disclosure. Therefore, the protection scope of the disclosure should be defined by the appended claims.

What is claimed is:

1. A semiconductor structure, comprising:
a substrate having a front side and a back side opposite to each other;
a transistor device located on the front side, and comprising a first drift region and a second drift region, wherein the first drift region and the second drift region are located in the substrate;
a first back gate located on the back side, and extending into the first drift region;
a second back gate located on the back side, and extending into the second drift region; and
a dielectric layer located between the first back gate and the substrate, and between the second back gate and the substrate.

2. The semiconductor structure of claim 1, further comprising:
a conductive layer located on the first back gate and the second back gate, and electrically connected to the first back gate and the second back gate.

3. The semiconductor structure of claim 1, wherein the transistor device further comprises:
a gate located on the front side, and positioned above a portion of the first drift region and a portion of the second drift region; and
a gate dielectric layer located between the gate and the substrate.

4. The semiconductor structure of claim 3, wherein
the first back gate has a first protrusion extending into the first drift region, and
the second back gate has a second protrusion extending into the second drift region.

5. The semiconductor structure of claim 4, wherein
the gate has a first sidewall and a second sidewall opposite to each other,
the first sidewall is positioned directly above the first drift region,
the second sidewall is positioned directly above the second drift region,
the first protrusion has a third sidewall away from the second protrusion, and
the second protrusion has a fourth sidewall away from the first protrusion.

6. The semiconductor structure of claim 5, wherein
the third sidewall does not extend beyond the first sidewall, and
the fourth sidewall does not extend beyond the second sidewall.

7. The semiconductor structure of claim 5, wherein
the third sidewall is aligned with the first sidewall, and
the fourth sidewall is aligned with the second sidewall.

8. The semiconductor structure of claim 5, wherein
the third sidewall extends beyond the first sidewall, and
the fourth sidewall extends beyond the second sidewall.

9. The semiconductor structure of claim 3, wherein the transistor device further comprises:
a first isolation structure located in the first drift region; and
a second isolation structure located in the second drift region, wherein
the gate is located above a portion of the first isolation structure and a portion of the second isolation structure.

10. The semiconductor structure of claim 9, wherein the transistor device further comprises:
a first doped region located in the first drift region; and
a second doped region located in the second drift region, wherein the first isolation structure and the second isolation structure are located between the first doped region and the second doped region.

11. The semiconductor structure of claim 3, wherein the transistor device further comprises:
a first well region and a second well region located in the substrate on both sides of the gate, wherein the first drift region and the second drift region are located between the first well region and the second well region.

12. The semiconductor structure of claim 11, wherein the transistor device further comprises:
a first doped region located in the first well region; and
a second doped region located in the second well region.

13. The semiconductor structure of claim 11, wherein the transistor device further comprises:
a third well region, wherein the first drift region, the second drift region, the first well region, and the second well region are located in the third well region.

14. The semiconductor structure of claim 1, wherein the transistor device is mirror-symmetrical.

15. A manufacturing method of a semiconductor structure, comprising:
providing a substrate, wherein the substrate has a front side and a back side opposite to each other;
forming a transistor device on the front side, wherein the transistor device comprises a first drift region and a second drift region, and the first drift region and the second drift region are located in the substrate;
forming a first back gate and a second back gate on the back side, wherein the first back gate extends into the first drift region, and the second back gate extends into the second drift region; and
forming a first dielectric layer between the first back gate and the substrate, and between the second back gate and the substrate.

16. The manufacturing method of the semiconductor structure of claim 15, wherein a method of forming the first dielectric layer comprises:
performing patterning on the back side to form a first recess and a second recess, wherein the first recess exposes the first drift region, and the second recess exposes the second drift region; and
forming conformally the first dielectric layer on the back side and in the first recess and the second recess.

17. The manufacturing method of the semiconductor structure of claim 16, wherein
the first recess extends into the first drift region, and
the second recess extends into the second drift region.

18. The manufacturing method of the semiconductor structure of claim 16, wherein a method of forming the first back gate and the second back gate comprises:
forming a second dielectric layer on the first dielectric layer, wherein the second dielectric layer fills the first recess and the second recess; and
forming the first back gate and the second back gate in the second dielectric layer, wherein a portion of the first back gate is located in the first recess, and a portion of the second back gate is located in the second recess.

19. The manufacturing method of the semiconductor structure of claim 18, further comprising:
forming a conductive layer on the first back gate and the second back gate, wherein the conductive layer is electrically connected to the first back gate and the second back gate.

20. The manufacturing method of the semiconductor structure of claim 19, wherein a method of forming the conductive layer comprises:
forming a third dielectric layer on the second dielectric layer, the first back gate, and the second back gate; and
forming the conductive layer in the third dielectric layer.
